(19) United States
(12) Patent Application Publication
(10) Pub. No.: US 2025/0185273 A1
(43) Pub. Date: Jun. 5, 2025

(54) HIGH ELECTRON MOBILITY TRANSISTOR

(71) Applicant: HiPer Semiconductor Inc., Taipei City (TW)

(72) Inventors: WEI-CHEN YANG, Hsinchu County (TW); WEI-CHIH HO, Hsinchu County (TW)

(73) Assignee: HiPer Semiconductor Inc., Taipei City (TW)

(21) Appl. No.: 18/937,045

(22) Filed: Nov. 5, 2024

(30) Foreign Application Priority Data
Dec. 1, 2023 (TW) 112146822

(51) Int. Cl. H01L 29/778; H01L 29/06; H01L 29/20; H01L 29/423; H01L 29/66

(52) U.S. Cl. CPC H10D 30/475; H10D 30/015; H10D 62/10; H10D 62/8503; H10D 64/513

(57) ABSTRACT

A high electron mobility transistor includes a semiconductor structure, a stepped trench, an electrode, and a gate. The semiconductor structure includes a barrier layer and a channel layer. The barrier layer is disposed on the channel layer. A two-dimensional electron gas is formed at an interface between the channel layer and the barrier layer. The stepped trench is disposed in the semiconductor structure. The electrode is disposed in the stepped trench. The gate is disposed on the barrier layer. The stepped trench has a first width and a second width. The first width is greater than the second width.

### BACKGROUND OF THE INVENTION

### Technical Field

The present invention relates generally to a high electron mobility transistor, and more particularly to a high electron mobility transistor having a stepped trench.

### Description of Related Art

A high electron mobility transistor (HEMT) is typically a structure having a heterojunction formed on a substrate, wherein a two-dimensional electron gas (2DEG) is formed on the heterojunction between two materials with different energy gaps. As the HEMT makes use of the 2DEG having a high electron mobility as a carrier channel of the transistor, the HEMT has features of a high breakdown voltage, the high electron mobility, a low on-resistance, and a low input capacitance, thereby the HEMT could be widely applied to high power semiconductor devices.

Reliability issues due to low breakdown voltage, high electric field, and on-resistance deterioration are three main problems of the HEMT. Conventionally, a drain field plate is provided to resolve the aforementioned technical problems. However, the improvement of the high electric field at the drain by providing the drain field plate is limited, and the size of the integrated circuit could not be effectively reduced by the conventional way. Therefore, how to provide a high electron mobility transistor which could increase a breakdown voltage and decrease an electric field and an on-resistance deterioration speed, is a problem needed to be solved in the industry.

### BRIEF SUMMARY OF THE INVENTION

In view of the above, the primary objective of the present invention is to provide a high electron mobility transistor which could increase a breakdown voltage and decrease an electric field and an on-resistance deterioration speed.

The present invention provides a high electron mobility transistor including a semiconductor structure, a stepped trench, an electrode, and a gate. The semiconductor structure includes a barrier layer and a channel layer. The barrier layer is disposed on the channel layer. In the channel layer, a two-dimensional electron gas is formed at an interface between the channel layer and the barrier layer. The stepped trench is disposed in the semiconductor structure. The electrode is disposed in the stepped trench. The gate is disposed on the barrier layer. The stepped trench has a first width and a second width. The first width is greater than the second width.

In an embodiment, the stepped trench has a top portion and a bottom portion. The top portion of the stepped trench has the first width. The bottom portion of the stepped trench has the second width.

In an embodiment, the stepped trench has a bottom portion located in the channel layer.

In an embodiment, the stepped trench has a bottom portion located in the barrier layer.

In an embodiment, a side of the stepped trench has a first corner and a second corner. The first corner has a first vertex. The second corner has a second vertex. A distance between the first vertex and the second vertex is less than or equal to 5 um.

In an embodiment, the stepped trench includes a plurality of steps. The plurality of steps include between two steps and five steps.

In an embodiment, the stepped trench includes a plurality of steps. A depth of each of the plurality of steps ranges between 1 nm and 100 nm.

In an embodiment, the stepped trench has a first step and a second step. A side of the first step close to gate has a first side wall. A side of the second step close to the gate has a second side wall. A distance between the first side wall and the second side wall ranges between 0.1 um and 5 um.

In an embodiment, the stepped trench has a first step. A side of the first step close to the gate has a first side wall. A side of the gate close to the electrode has a first side. A side of the electrode close to the first side of the gate has a second side. A distance between the second side and the first side wall is between 0.1 um and 10 um.

In an embodiment, a material of the electrode includes a metal or a metal and a n-type nitride.

In an embodiment, when the material of the electrode comprises the metal and the n-type nitride, a thickness of the n-type nitride is greater than or equal to 5 nm. The n-type nitride is n-type doped by doping, diffusion, or ion implantation.

In an embodiment, when the material of the electrode comprises the metal and the n-type nitride, the n-type nitride includes at least one stacked layer. The at least one stacked layer has a nitride.

In an embodiment, when the material of the electrode comprises the metal and the n-type nitride, the n-type nitride is formed on a bottom portion of the stepped trench, and the metal is disposed on the n-type nitride.

In an embodiment, when the material of the electrode comprises the metal and the n-type nitride, the n-type nitride is formed in the stepped trench and on the barrier layer, and the metal is disposed on the n-type nitride.

In an embodiment, the high electron mobility transistor further includes at least one n-type structure formed on the barrier layer. The electrode is a drain. The at least one n-type structure is disposed between the gate and the drain.

In an embodiment, a part of the drain is formed on the barrier layer. The drain is in contact with the at least one n-type structure.

In an embodiment, the high electron mobility transistor further includes another stepped trench and another electrode. The another electrode is a source and is disposed in the another stepped trench.

In an embodiment, the semiconductor structure has a top surface. An opening of the stepped trench has a plurality of protrusions on the top surface.

With the aforementioned design, by the electrode disposed in the stepped trench, the breakdown voltage could be increased and the electric field and the on-resistance deterioration speed could be decreased.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a schematic sectional view of the high electron mobility transistor according to a first embodiment of the present invention;

FIG. 2 is a schematic sectional view, showing the first trench according to the first embodiment of the present invention is etched on the barrier layer by the first dry etch process;

FIG. 3 is a schematic sectional view, showing the second trench according to the first embodiment of the present invention is etched on the channel layer by the second dry etch process.

FIG. 4 is a schematic view showing a relationship between the drain current and the drain voltage of the high electron mobility transistor of the first embodiment and a comparative example;

FIG. 5 is a schematic view showing a relationship between the drain current and the gate voltage of the high electron mobility transistor of the first embodiment and the comparative example;

FIG. 6 is a schematic top view of the stepped trench of the high electron mobility transistor according to another embodiment of the present invention;

FIG. 7 is a schematic top view of the stepped trench of the high electron mobility transistor according to the another embodiment of the present invention, showing the protrusions in another shape;

FIG. 8 is a schematic sectional view of the high electron mobility transistor according to a second embodiment of the present invention;

FIG. 9 is a schematic sectional view of the high electron mobility transistor according to a third embodiment of the present invention;

FIG. 10 is a schematic sectional view of the high electron mobility transistor according to a fourth embodiment of the present invention; and

FIG. 11 is a schematic sectional view of the high electron mobility transistor according to a fifth embodiment of the present invention;

### DETAILED DESCRIPTION OF THE INVENTION

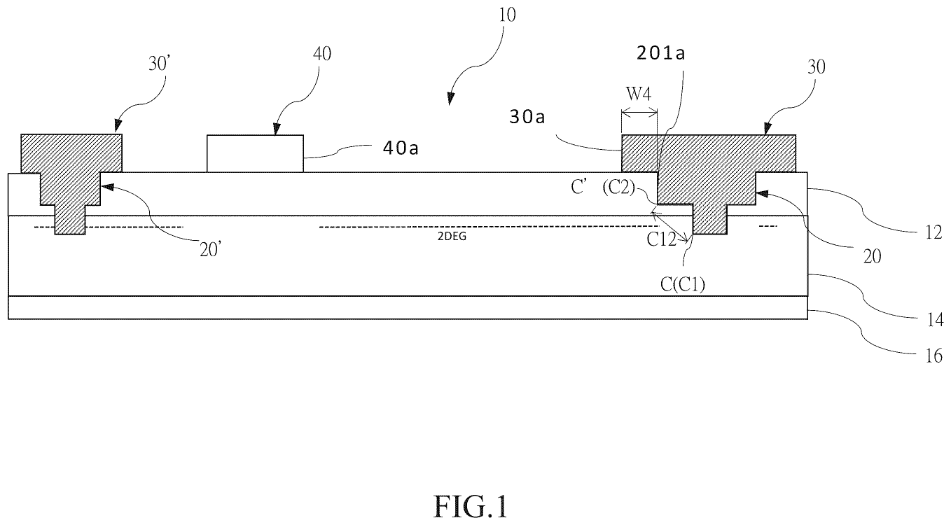

A high electron mobility transistor according to a first embodiment of the present invention is illustrated in FIG. 1 and includes a semiconductor structure 10, a stepped trench 20, an electrode 30, and a gate 40. The semiconductor structure 10 includes a barrier layer 12, a channel layer 14, and a substrate 16. The barrier layer 12 is disposed on the channel layer 14. The channel layer 14 is disposed on the substrate 16. In the channel layer 14, a two-dimensional electron gas (2DEG) is formed at an interface between the channel layer 14 and the barrier layer 12. The stepped trench 20 is disposed in the semiconductor structure 10. The electrode 30 is disposed in the stepped trench 20 and on the barrier layer 12. Another electrode 30′ is disposed in another stepped trench 20′ and on the barrier layer 12. The gate 40 is disposed on the barrier layer 12.

The substrate 16 could be a silicon substrate, a silicon carbide substrate, or a sapphire substrate. The channel layer 14 could be a gallium nitride (GaN) channel layer. The barrier layer 12 could be an aluminum-gallium nitride (AlGaN) barrier layer. A material of the electrode 30 includes a metal. In the current embodiment, the electrode 30 is an electrode made of a metal, wherein the metal could be, for example, titanium or aluminum. In the current embodiment, the gate 40 could be a p-type doped gallium nitride (pGaN) gate 40. In other embodiments, the gate 40 could be a n-type doped gallium nitride (nGaN) gate 40 or a metal structure. The high electron mobility transistor according to the first embodiment of the present invention is an enhancement mode gallium nitride (E-Mode GaN) transistor. In other embodiments, the high electron mobility transistor could be a depletion mode gallium nitride (D-Mode GaN) transistor.

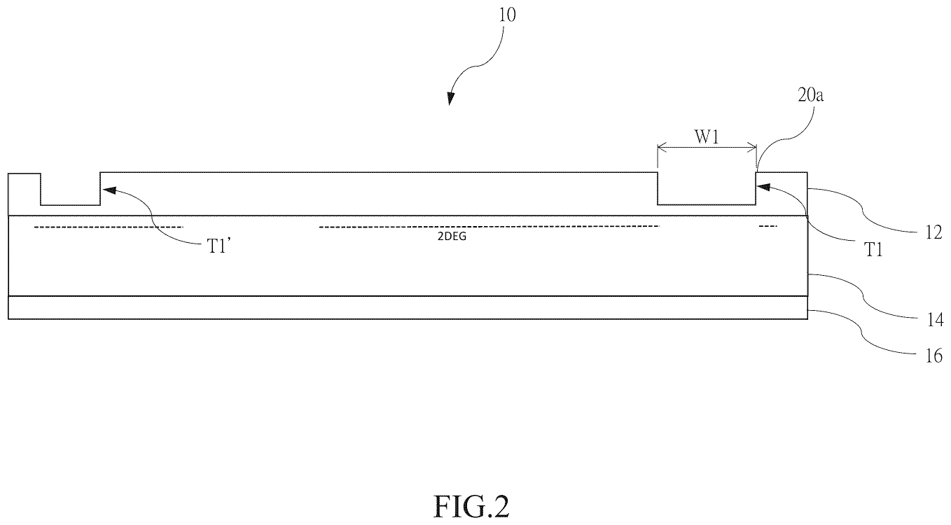

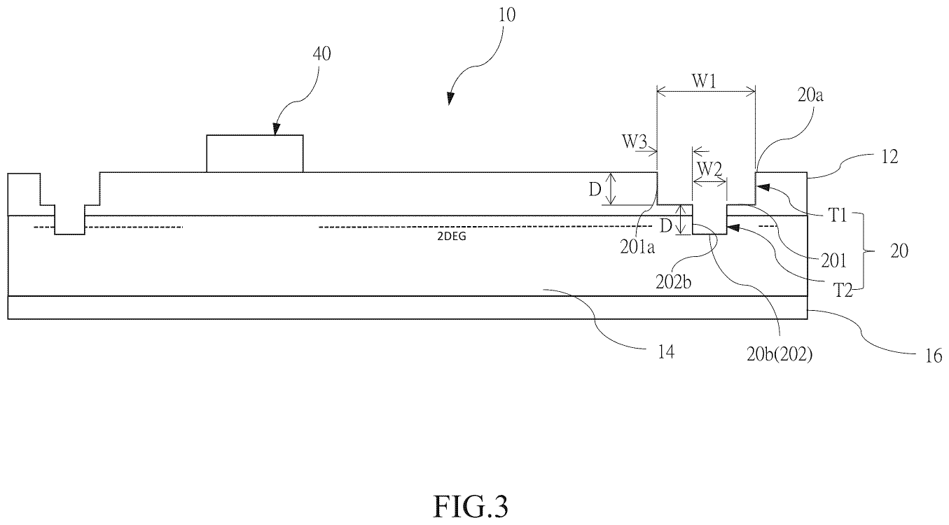

In the current embodiment, the stepped trench 20 is formed as shown in FIG. 2 and FIG. 3, wherein firstly a first trench T1 is etched on the barrier layer 12 by a first dry etch process shown in FIG. 2, and then a second trench T2 is etched on the channel layer 14 by a second dry etch process shown in FIG. 3, so that the stepped trench 20 having two steps are formed. Afterwards, a metal layer is formed on the semiconductor structure 10 and is filled into the stepped trench 20. Then a position of the metal layer is defined as shown in FIG. 1 to form the electrode 30. In the current embodiment, the electrode 30 is a drain, and a part of the electrode 30 is formed on the barrier layer 12.

As shown in FIG. 3, a depth D of each of the steps of the stepped trench 20 ranges between 1 nm and 100 nm. Preferably, the depth D of each of the steps of the stepped trench 20 ranges between 1 nm and 50 nm. The depth D of each of the steps of the stepped trench 20 could be identical or different.

Referring to FIG. 1, a side of the stepped trench 20 facing the gate 40 has a first corner C and a second corner C′. The first corner C has a first vertex C1. The second corner C′ has a second vertex C2. A minimum distance C12 between the first vertex C1 and the second vertex is less than or equal to 5 um. Referring to FIG. 2 and FIG. 3, in the current embodiment, the stepped trench 20 has a first width W1 and a second width W2 (shown in FIG. 3), wherein the first width W1 is greater than the second width W2. The stepped trench 20 has a top portion 20a and a bottom portion 20b. The top portion 20a of the stepped trench 20 has the first width W1. The bottom portion 20b of the stepped trench 20 has the second width W2. The bottom portion 20b is located in the channel layer 14. Thus, the stepped trench 20 with a wide top and a narrow bottom is formed.

Referring to FIG. 3, in the current embodiment, the stepped trench 20 has a first step 201 and a second step 202. The first trench T1 has the first step 201. The second trench T2 has the second step 202. A side of the first step 201 close to the gate 40 has a first side wall 201a. A side of the second step 202 close to the gate 40 has a second side wall 202b. A distance W3 between the first side wall 201a and the second side wall 202b ranges between 0.1 um and 5 um, preferably between 0.4 um and 2 um. As shown in FIG. 1, a side of the gate 40 close to the electrode 30 has a first side 40a. A side of the electrode 30 close to the first side 40a of the gate 40 has a second side 30a. A distance W4 between the second side 30a and the first side wall 201a is between 0.1 um and 10 um, preferably between 1 um and 9 um. In other embodiments, the number of the steps of the stepped trench 20 could be plural, preferably between 2 steps and 5 steps.

Additionally, in the current embodiment, a side of the stepped trench 20 close to the gate 40 and another side of the stepped trench 20 away from the gate 40 respectively have a plurality of steps as an example for illustration. In other embodiments, a plurality of steps could be only provided on the side of stepped trench 20 close to the gate 40, and a contour of the another side of the stepped trench 20 away from the gate 40 could be provided without the steps.

Referring to FIG. 1, in the current embodiment, the high electron mobility transistor includes another stepped trench 20′ and another electrode 30′. The another electrode 30′ is a source and is disposed in the another stepped trench 20′. The formation of the another stepped trench 20′ and the another electrode 30′ is almost the same as the aforementioned formation of the stepped trench 20 and the electrode 30 and could be simultaneously performed with the formation of the stepped trench 20 and the electrode 30. The structure of the another stepped trench 20′ and the another electrode 30′ is the same as that of the stepped trench 20 and the electrode 30. In other embodiments, only the drain could be disposed in the stepped trench 20, while the source is directly disposed, for example, on the barrier layer 12 instead of being disposed in the stepped trench.

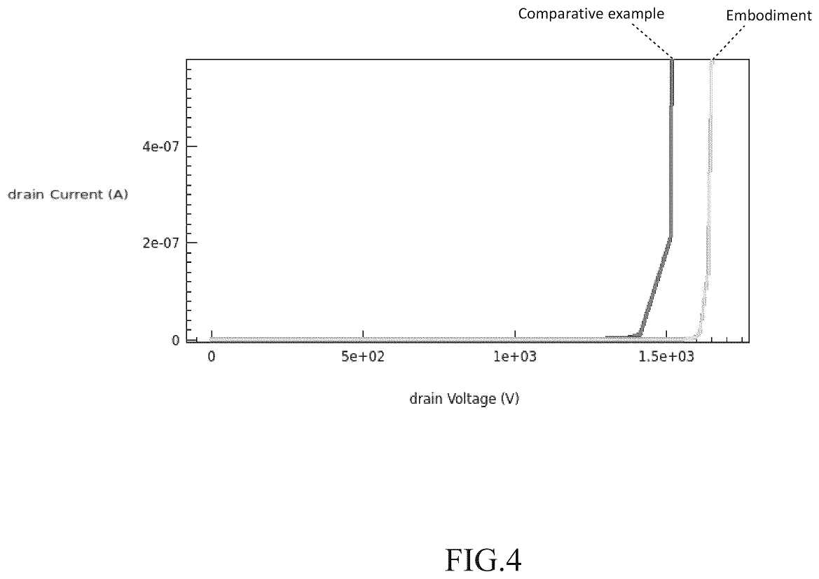

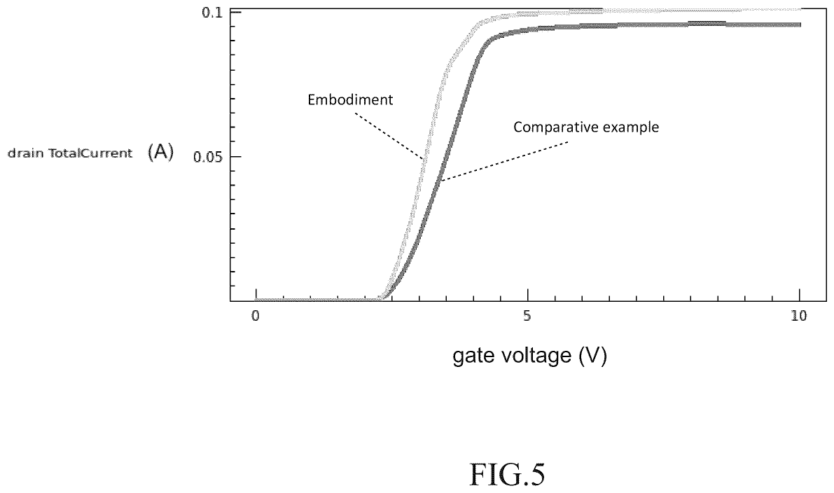

FIG. 4 is a schematic view showing a relationship between a drain current and a drain voltage of the high electron mobility transistor of the first embodiment and a high electron mobility transistor of a comparative example, and FIG. 5 is a schematic view showing a relationship between the drain current and a gate voltage of the high electron mobility transistor of the first embodiment and the high electron mobility transistor of the comparative example. The difference between the high electron mobility transistor of the comparative example and the high electron mobility transistor of the first embodiment is that the high electron mobility transistor of the comparative example does not have a stepped trench and the source electrode and the drain electrode are directly disposed on the barrier layer. It can be seen from FIG. 4 and FIG. 5 that compared to the comparative example, the breakdown voltage and the drain current of the high electron mobility transistor could be effectively improved by disposing the electrode 30 in the stepped trench 20 of the first embodiment.

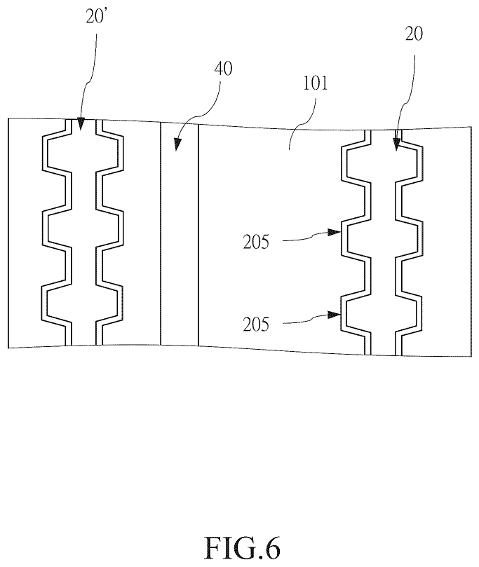

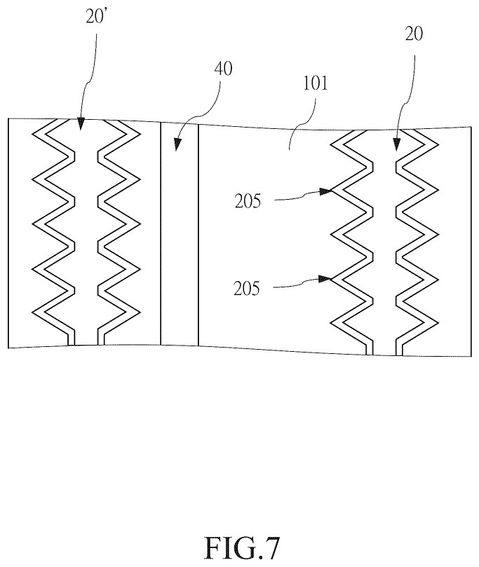

Referring to FIG. 6 and FIG. 7, an opening of the stepped trench 20 could have a plurality of protrusions 205 on a top surface 101 of the semiconductor structure 10. By the protrusions 205, a cross-sectional area of the stepped trench 20 on the top surface 101 of the semiconductor structure 10 could be effectively increased, so that a contact resistance between the electrode 30 and the stepped trench 20 could be reduced, thereby reducing the on-resistance.

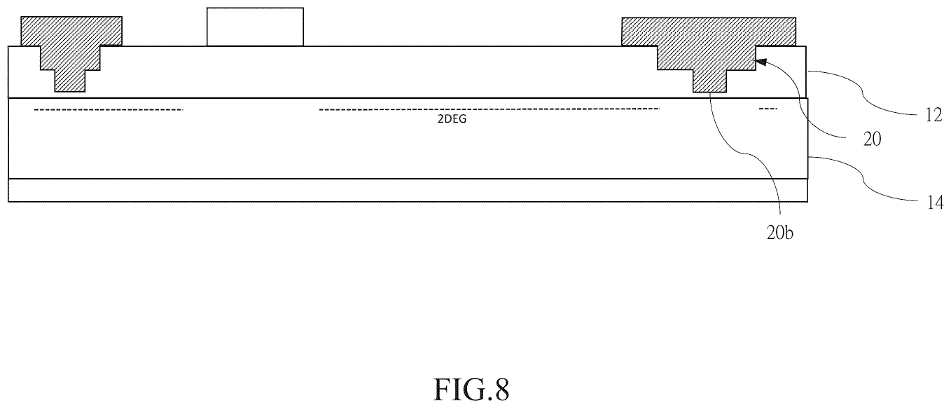

A high electron mobility transistor according to a second embodiment of the present invention is illustrated in FIG. 8 and has almost the same structure as that of the high electron mobility transistor of the first embodiment, except that the bottom portion 20b of the stepped trench 20 of the first embodiment is located in the channel layer 14 as an example, but the bottom portion 20b of the stepped trench 20 of the second embodiment is located in the barrier layer 12, which could also achieve the purpose of improving the breakdown voltage and the drain current of the high electron mobility transistor.

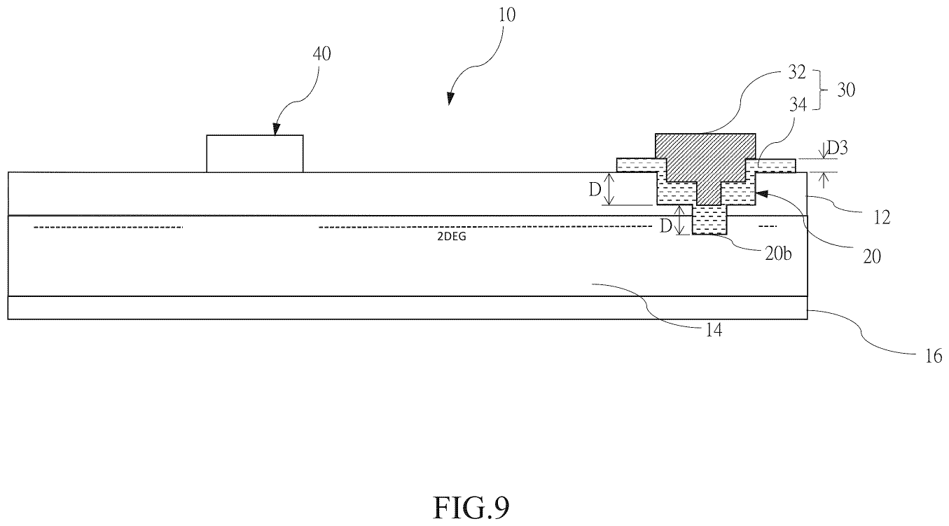

A high electron mobility transistor according to a third embodiment of the present invention is illustrated in FIG. 9 and has almost the same structure as that of the high electron mobility transistor of the first embodiment, except that the electrode 30 of the third embodiment does not only include a metal 32 but also includes a n-type nitride 34. The stepped trench 20 of the third embodiment is the same as the stepped trench 20 of the first embodiment, i.e., the stepped trench 20 with two steps is formed by the first dry etch process and the second dry etch process. Then, a n-type nitride layer is deposited on the semiconductor structure 10 by atomic layer deposition (ALD) or metal organic chemical vapor deposition (MOCVD). The n-type nitride layer is filled in the stepped trench 20. A position of the n-type nitride 34 is defined (shown in FIG. 9) and a part of the n-type nitride 34 is formed on the barrier layer 12. Afterwards, a metal layer is formed on the semiconductor structure 10, wherein a part of the metal layer is stacked on the n-type nitride 34 and a position of the metal 32 is defined. In this way, the n-type nitride 34 is formed on the bottom portion 20b of the stepped trench 20, and the metal 32 is disposed on the n-type nitride 34, so that the electrode 30 including the n-type nitride 34 and the metal 32 is formed. In the current embodiment, the electrode 30 is a drain.

As shown in FIG. 9, the depth D of each of the steps of the stepped trench 20 ranges between 1 nm and 100 nm, preferably between 1 nm and 50 nm. The depth D of each of the steps could be identical or different.

The n-type nitride 34 could be a nitride, such as GaN, AlN, InN, AlGaN, InGaN, InAlGaN, etc., doped with a n-type dopant by doping, diffusion, or ion implantation. The n-type nitride 34 could be a single-layer nitride stacked layer structure or a structure including a plurality of nitride stacked layers A thickness D3 of the n-type nitride 34 is greater than or equal to 5 nm. As shown in FIG. 9, the thickness D3 is a distance between a top surface of the barrier layer 12 and a top surface of the n-type nitride 34.

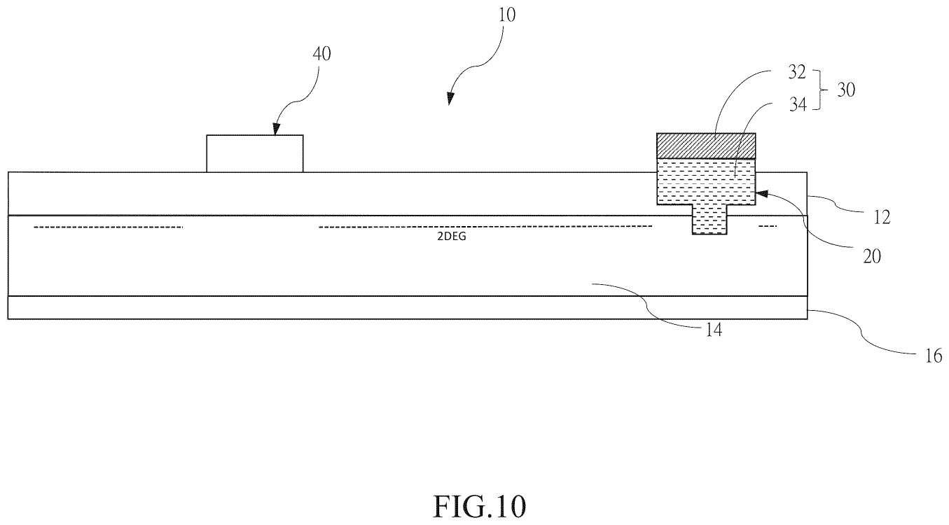

A high electron mobility transistor according to a fourth embodiment of the present invention is illustrated in FIG. 10 and has almost the same structure as that of the high electron mobility transistor of the third embodiment, except that the n-type nitride 34 of the fourth embodiment could be provided without being formed on the top surface of the barrier layer12, which could also achieve the effect of improving the breakdown voltage and the drain current of the high electron mobility transistor.

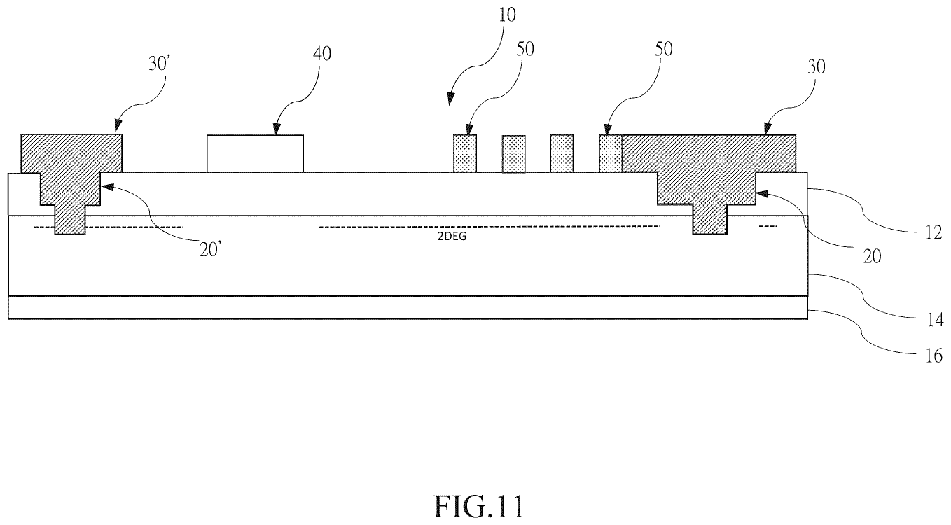

A high electron mobility transistor according to a fifth embodiment of the present invention is illustrated in FIG. 11 and has almost the same structure as that of the high electron mobility transistor of the first embodiment, except that the high electron mobility transistor of the fifth embodiment includes a plurality of n-type structures 50 formed on the barrier layer 12, wherein the n-type structures 50 are disposed between the gate 40 and the electrode 30 that is the drain. In this way, the n-type structures 50 could improve a carrier concentration of the two-dimension electron gas and disperse an electric field of a drain side. The n-type structures 50 could be a nitride, such as GaN, AlN, InN, AlGaN, InGaN, InAlGaN, etc., doped with a n-type dopant by doping, diffusion, or ion implantation. The drain is in contact with one of the n-type structures 50. Moreover, in other embodiments, the number of the n-type structure 50 could be one or plural, which could also achieve the effect of improving the carrier concentration of the two-dimensional electron gas and dispersing the electric field of the drain side.

With the aforementioned design, by disposing the electrode in the stepped trench, the breakdown voltage could be improved and the electric field and the on-resistance deterioration speed could be reduced.

It must be pointed out that the embodiments described above are only some preferred embodiments of the present invention. All equivalent structures and methods which employ the concepts disclosed in this specification and the appended claims should fall within the scope of the present invention.

What is claimed is:

1. A high electron mobility transistor, comprising:
a semiconductor structure comprising a barrier layer and a channel layer, wherein the barrier layer is disposed on the channel layer, wherein in the channel layer, a two-dimensional electron gas is formed at an interface between the channel layer and the barrier layer;
a stepped trench disposed in the semiconductor structure;
an electrode disposed in the stepped trench; and
a gate disposed on the barrier layer;
wherein the stepped trench has a first width and a second width; the first width is greater than the second width;
wherein a side of the stepped trench has a first corner and a second corner; the first corner has a first vertex; the second corner has a second vertex; a distance between the first vertex and the second vertex is less than or equal to 5 um.

2. The high electron mobility transistor as claimed in claim 1, wherein the stepped trench has a top portion and a bottom portion; the top portion of the stepped trench has the first width, and the bottom portion of the stepped trench has the second width.

3. The high electron mobility transistor as claimed in claim 1, wherein the stepped trench has a bottom portion located in the channel layer.

4. The high electron mobility transistor as claimed in claim 1, wherein the stepped trench has a bottom portion located in the barrier layer.

5. The high electron mobility transistor as claimed in claim 1, wherein the stepped trench comprises a plurality of steps; the plurality of steps comprises between two steps and five steps.

6. The high electron mobility transistor as claimed in claim 1, wherein the stepped trench comprises a plurality of steps; a depth of each of the plurality of steps ranges between 1 nm and 100 nm.

7. The high electron mobility transistor as claimed in claim 1, wherein the stepped trench has a first step and a second step; a side of the first step close to the gate has a first side wall; a side of the second step close to the gate has a second side wall; a distance between the first side wall and the second side wall ranges between 0.1 um and 5 um.

8. The high electron mobility transistor as claimed in claim 1, wherein the stepped trench has a first step; a side of the first step close to the gate has a first side wall; a side of the gate close to the electrode has a first side; a side of the electrode close to the first side of the gate has a second side; a distance between the second side and the first side wall is between 0.1 um and 10 um.

9. The high electron mobility transistor as claimed in claim 1, wherein a material of the electrode comprises a metal or a metal and a n-type nitride.

10. The high electron mobility transistor as claimed in claim 9, wherein when the material of the electrode comprises the metal and the n-type nitride, a thickness of the n-type nitride is greater than or equal to 5 nm; the n-type nitride is n-type doped by doping, diffusion, or ion implantation.

11. The high electron mobility transistor as claimed in claim 9, wherein when the material of the electrode comprises the metal and the n-type nitride, the n-type nitride comprises at least one stacked layer; the at least one stacked layer has a nitride.

12. The high electron mobility transistor as claimed in claim 9, wherein when the material of the electrode comprises the metal and the n-type nitride, the n-type nitride is formed on a bottom portion of the stepped trench, and the metal is disposed on the n-type nitride.

13. The high electron mobility transistor as claimed in claim 9, wherein when the material of the electrode comprises the metal and the n-type nitride, the n-type nitride is formed in the stepped trench and on the barrier layer, and the metal is disposed on the n-type nitride.

14. The high electron mobility transistor as claimed in claim 1, further comprising at least one n-type structure formed on the barrier layer, wherein the electrode is a drain; the at least one n-type structure is disposed between the gate and the drain.

15. The high electron mobility transistor as claimed in claim 14, wherein a part of the drain is formed on the barrier layer; the drain is in contact with the at least one n-type structure.

16. The high electron mobility transistor as claimed in claim 1, further comprising another stepped trench and another electrode, wherein the another electrode is a source and is disposed in the another stepped trench.

17. The high electron mobility transistor as claimed in claim 1, wherein the semiconductor structure has a top surface; an opening of the stepped trench has a plurality of protrusions on the top surface.
